(19) United States
(12) Patent Application Publication
(10) Pub. No.: US 2017/0105318 A1
(43) Pub. Date: Apr. 13, 2017

(54) CONTAINER DATA CENTER

(71) Applicant: HON HAI PRECISION INDUSTRY CO., LTD., New Taipei (TW)

(72) Inventors: TZE-CHERN MAO, New Taipei (TW); CHIH-HUNG CHANG, New Taipei (TW); YEN-CHUN FU, New Taipei (TW); YAO-TING CHANG, New Taipei (TW); CHAO-KE WEI, New Taipei (TW); HUNG-CHOU CHAN, New Taipei (TW)

(21) Appl. No.: 14/942,197

(22) Filed: Nov. 16, 2015

(30) Foreign Application Priority Data
Oct. 13, 2015 (TW) 104133433

(51) Int. Cl. H05K 7/20; H05K 7/14

(52) U.S. Cl. CPC H05K 7/20736; H05K 7/1488

(57) ABSTRACT

A container data center includes a container, two server cabinet groups, and a power supply equipment group. The container includes an interior. The two server cabinet groups are respectively arranged at two opposite ends of the interior of the container. The power supply equipment group is arranged in the container between the two server cabinet groups.

### FIELD

The subject matter herein generally relates to a container data center.

### BACKGROUND

A container data center can include a container, a number of server cabinets arranged at an end of the interior of the container, and a power supply equipment group arranged at an opposite end of the interior of the container.

### BRIEF DESCRIPTION OF THE DRAWINGS

Implementations of the present technology will now be described, by way of example only, with reference to the figures.

FIG. 1 is a top plan, diagrammatic view of an embodiment of a container data center.

FIG. 2 is a side plan, diagrammatic view of the container data center of FIG. 1 in use.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiment described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts have been exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “outside” refers to a region that is beyond the outermost confines of a physical object. The term “inside” indicates that at least a portion of a region is partially contained within a boundary formed by the object. The term “comprising,” when utilized, means “including, but not necessarily limited to”; it specifically indicates open-ended inclusion or membership in the so-described combination, group, series and the like.

The present disclosure described in relation to a container data center.

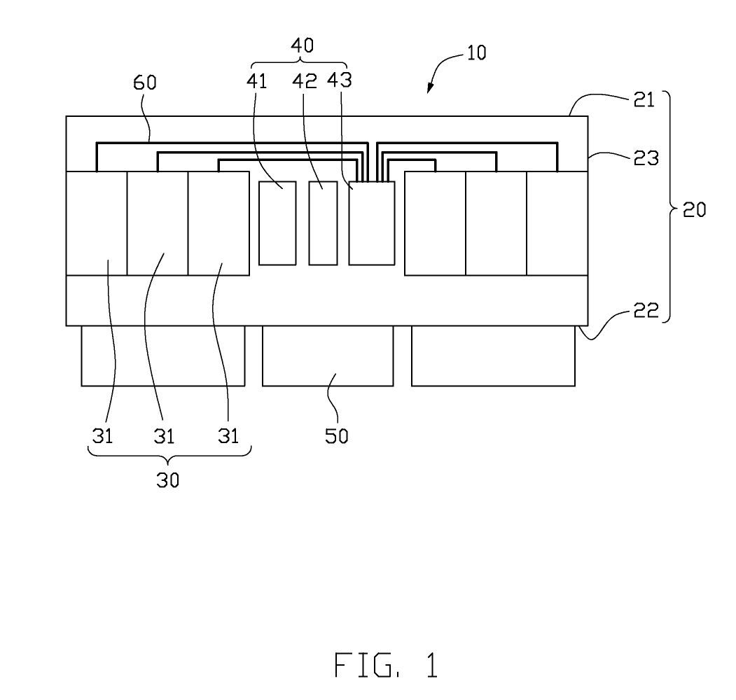

FIG. 1 illustrates an embodiment of a container data center 10. The container data center 10 comprises a container 20, two server cabinet groups 30, a power supply equipment group 40, and a plurality of air handing units 50.

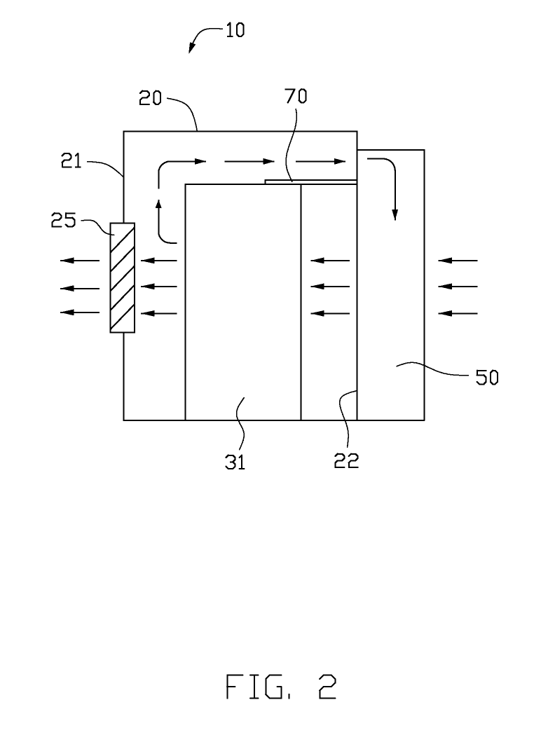

The container 20 includes a first sidewall 21, a second sidewall 22 opposite to the first sidewall 21, and two opposite end walls 23 connected between the first sidewall 21 and the second sidewall 22. A plurality of windows 25 (see FIG. 2) is horizontally aligned in the first sidewall 21.

The server cabinet groups 30 are respectively arranged at two opposite ends of the interior of the container 20. Each server cabinet group 30 comprises a plurality of spaced or adjoining server cabinets 31.

The power supply equipment group 40 is arranged in the container 20 between the two server cabinet groups 30. The power supply equipment group 40 comprises a battery cabinet 41, an UPS cabinet 42, and a power distribution cabinet 43. The battery cabinet 41, the UPS cabinet 42, and the power distribution cabinet 43 adjoin with or are spaced from each other, and adjoin with or are spaced from adjacent one of the server cabinets 31. The power supply equipment group 40 and the server cabinet groups 30 are spaced from the first sidewall 21 and the second sidewall 22, and are aligned in a line parallel to the first sidewall 21 and the second sidewall 22. A power cable 60 is coupled between the power distribution cabinet 43 and each server cabinet 31.

The air handing units 50 are mounted to an outside of the second sidewall 22, for dissipating heat and dehumidifying for the interior of the container 20. In at least one embodiment, the number of the air handing units 50 is three, the three air handing units 50 respectively align with the power supply equipment group 40 and the two server cabinet groups 30. A stop plate 70 is coupled between the second sidewall 22 and tops of the power supply equipment group 40 and the server cabinet groups 30, for isolating hot air from cool air.

During operation of the container data center 10, when air temperature outside of the container 20 is high, the windows 25 are closed. A refrigeration mode of the air handing units 50 is turned on. The air handing units 50 blow cool air into the container 20 through a lower portion of the second sidewall 22. The cool air becomes hot air after heat is exchanged with the server cabinet groups 30 and the power supply equipment group 40. The hot air flows up in an interspace between the first sidewall 21, the server cabinet groups 30, and the power supply equipment group 40, and then the hot air flows into the air handing units 50 through an upper portion of the second sidewall 22 above the stop plate 70. The server cabinet groups 30 at two ends of the container 20 produce more heat than the power supply equipment group 40, the middle one of the air handing units 50 aligning with the power supply equipment group 40 can dissipate heat for the power supply equipment group 40 and the server cabinet groups 30 at two sides of the power supply equipment group 40, which make the air handing units 50 be effectively used.

FIG. 2 shows the container data center 10 in a different state. When air temperature outside of the container 20 is low and air humidity outside of the container 20 is high, the windows 25 are open. A dehumidification mode of the air handing units 50 can be turned on. Cold air outside of the container data center 10 flows into the air handing units 50 and is mixed together with the hot air flowing into the air handing units 50 from the interior of the container 20 to form cool air. The cool air flows into the container 20 through the lower portion of the second sidewall 22. The cool air becomes hot air after heat is exchanged with the server cabinet groups 30 and the power supply equipment group 40. A portion of the volume of the hot air is discharged outside through the open windows 25. The other portion of the volume of the hot air flows in the interspace between the first sidewall 21, the server cabinet groups 30, and the power supply equipment group 40. Then the hot air flows into the air handing units 50 through an upper portion of the second sidewall 22 above the stop plate 70, and is mixed together with cold air from outside of the container data center 10 to form cool air. The power supply equipment group 40 in a middle of the container 20 produces less heat than the server cabinet groups 30 at two sides of the power supply equipment group 40, the server cabinet groups 30 can provide more hot air to the middle one of the air handing units 50 to dehumidify for the cold air, which make the air handing units 50 be effectively used.

The arrangement inside the container data center 10 is rational, and heat produced by the power supply equipment group 40 and the server cabinet groups 30 in the container data center 10 is distributed evenly, which make the air handing units 50 be effectively used. Furthermore, because the power supply equipment group 40 is arranged in the middle of the container 20, the power cables 60 connected between the power supply equipment group 40 and the server cabinets 31 are shorter than power cables in a traditional container data center, which can reduce power loss, and prevent power cables from being arranged concentratedly to block hot air backflow.

It is to be understood, however, that even though numerous characteristics and advantages of the embodiments have been set forth in the foregoing description, together with details of the structure and function of the embodiments, the disclosure is illustrative only, and changes may be made in detail, especially in the matters of shape, size, and arrangement of parts within the principles of the disclosure to the full extent indicated by the broad general meaning of the terms in which the appended claims are expressed.

What is claimed is:

1. A container data center, comprising:
a container having an interior;
two server cabinet groups respectively arranged at two opposite ends of the interior of the container; and
a power supply equipment group arranged in the container between the two server cabinet groups.

2. The container data center of claim 1, wherein the container comprises a first sidewall and a second sidewall opposite to the first sidewall, the power supply equipment group and the server cabinet groups are aligned in a line parallel to the first sidewall and the second sidewall.

3. The container data center of claim 2, further comprising a plurality of air handing units mounted to an outside of the second sidewall, in communication with the interior of the container.

4. The container data center of claim 3, wherein a number of the air handing units is three, and the three air handing units respectively align with the power supply equipment group and the two server cabinet groups.

5. The container data center of claim 3, wherein a plurality of windows is horizontally aligned in the first sidewall.

6. The container data center of claim 5, wherein the first sidewall is spaced from the power supply equipment group and the two server cabinet groups.

7. The container data center of claim 6, wherein the second sidewall is spaced from the power supply equipment group and the two server cabinet groups, a stop plate is coupled between the second sidewall and tops of the power supply equipment group and the server cabinet groups, cool air in the air handing units flows into the container through a lower portion of the second sidewall and becomes hot air after heat is exchanged with the server cabinet groups and the power supply equipment group, at least one portion of the hot air flows up in an interspace between the first sidewall, the server cabinet groups, and the power supply equipment group, and into the air handing units through an upper portion of the second sidewall above the stop plate.

8. The container data center of claim 1, wherein each server cabinet group comprises a plurality of server cabinets, a power cable is coupled between each server cabinet and the power supply equipment group.

9. The container data center of claim 8, wherein the power supply equipment group comprises a battery cabinet, an UPS cabinet, and a power distribution cabinet, the power cable is coupled between each server cabinet and the power distribution cabinet.
